(19) United States
(12) Patent Application Publication
(10) Pub. No.: US 2014/0364046 A1
(43) Pub. Date: Dec. 11, 2014

(54) AIR GUIDING MODULE AND ELECTRONIC DEVICE WITH AIR GUIDING MODULE

(71) Applicants: HON HAI PRECISION INDUSTRY CO., LTD., New Taipei (TW); HONG FU JIN PRECISION INDUSTRY (ShenZhen) CO., LTD, Shenzhen (CN)

(72) Inventor: ZHAN-YANG LI, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 14/192,883

(22) Filed: Feb. 28, 2014

(30) Foreign Application Priority Data
Jun. 7, 2013 (CN) 2013102243713

(51) Int. Cl. H05K 7/20

(52) U.S. Cl. CPC H05K 7/20009
USPC 454/184; 454/324

(57) ABSTRACT

An air guiding module, is configured for guiding air flow in an enclosure, includes an air duct, a sliding member, and a limiting member. The sidling member is slidably mounted to the air guiding duct. The limiting member is secured to the air guiding duct and engages the sliding member with the air guiding duct. The sliding member is slidable relative to the air guiding duct and the limiting member to engage with the enclosure or disengage from the enclosure, to engage the air guiding duct with the enclosure or disengage the air guiding duct from the enclosure. The disclosure further discloses an electronic device with the air guiding module.

### FIELD

Embodiments of the present disclosure relate to electronic devices, and particularly to an electronic device with an air guiding module.

### BACKGROUND

An air guiding module is generally secured to an air outlet of a fan in an electronic device, to guide air to a heat-generating component, such as a CPU and a memory. However, the air guiding module is generally secured to an enclosure of the electronic device by screws, which requires a screw driver to secure the screws to the air guiding module. Disassembly or reassembly of the air guiding module can be tedious and inconvenient. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of an air guiding module and an enclosure.

FIG. 2 is an enlarged view of a circled portion II of FIG. 1.

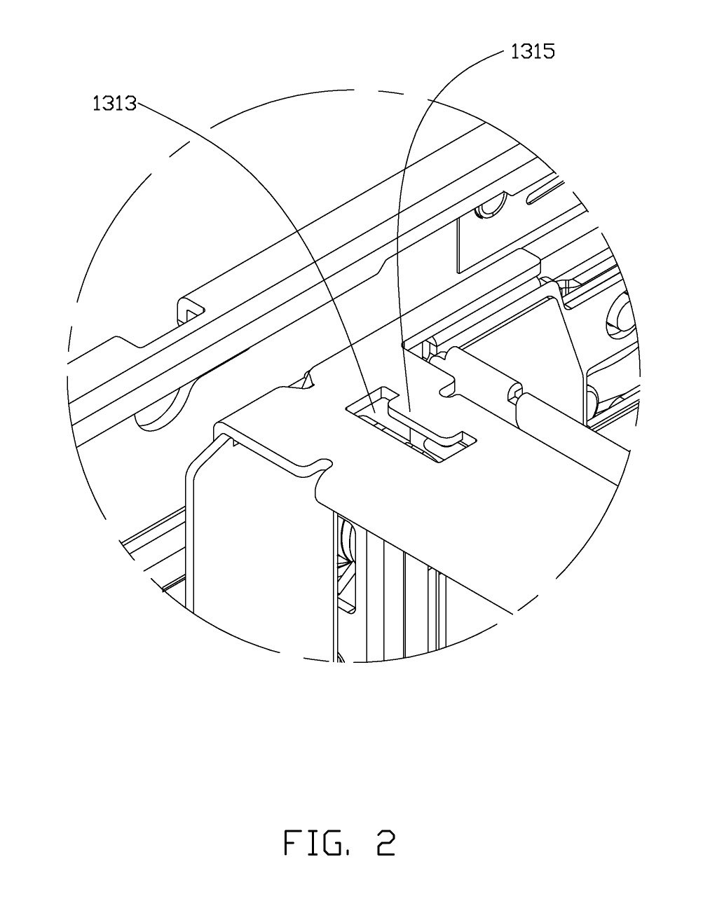

FIG. 3 is an isometric view of the air guiding module of FIG. 1, but viewed from a different aspect.

FIG. 4 is an exploded, isometric view of the air guiding module of FIG. 3.

FIG. 5 is an assembled, isometric view of the air guiding module and the enclosure of FIG. 1.

FIG. 6 is an assembled, isometric view of the air guiding module, a mounting bracket, and an installation bracket, showing a sliding member in a first position.

FIG. 7 is another assembled, isometric view of the air guiding module, the mounting bracket, and the installation bracket, showing the sliding member in a second position.

FIG. 8 is an enlarged view of a circled portion VIII of FIG. 7.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

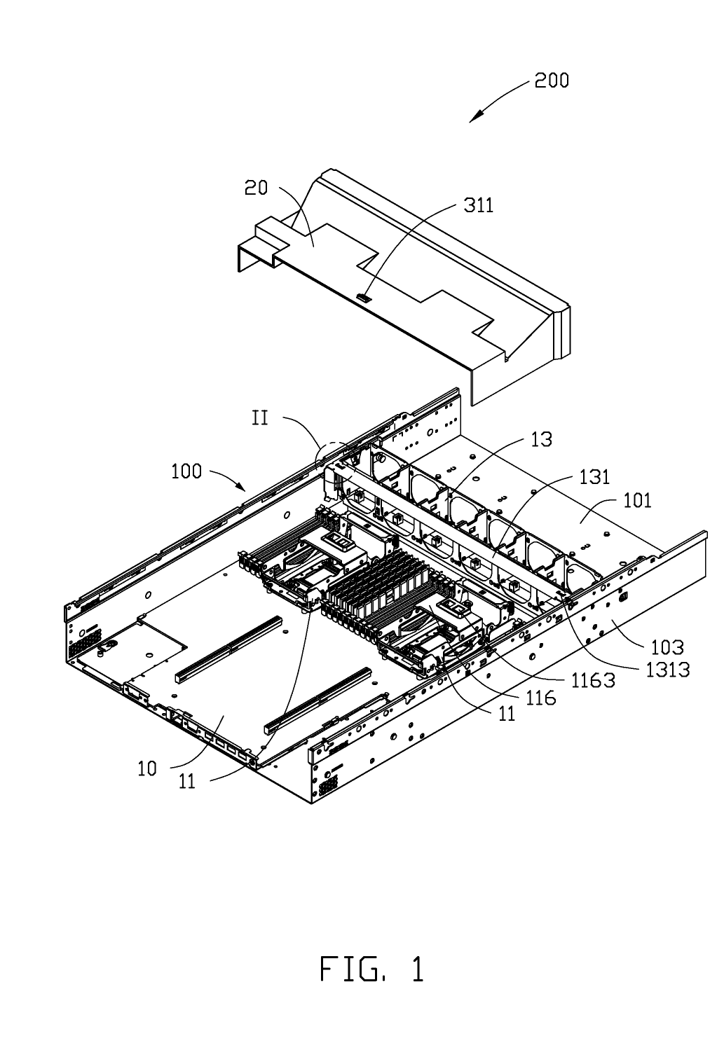

FIG. 1 shows one embodiment of an electronic device. The electronic device includes an enclosure 100 and an air guiding module 200.

The enclosure 100 includes a bottom plate 101 and opposite two side plates 103 extending upwards from opposite side edges of the bottom plate 101. A circuit board 10 is secured to the bottom plate 101. Two mounting brackets 11 and an installation bracket 13 are secured to the circuit board 10. Each mounting bracket 11 includes a mounting cover 116. The mounting cover 116 defines a mounting hole 1163. In one embodiment, the mounting hole 1163 is rectangular. The installation bracket 13 is used for securing a plurality of fans (not shown) and comprises a handle 131. The handle 131 is rotatable to move the installation bracket 13. Each opposite end of the handle 131 defines an installation slot 1313. In one embodiment, the installation slot 1313 is rectangular. A limiting piece 1315 extends from an edge of the installation slot 1313 towards an opposite edge of the installation slot 1313.

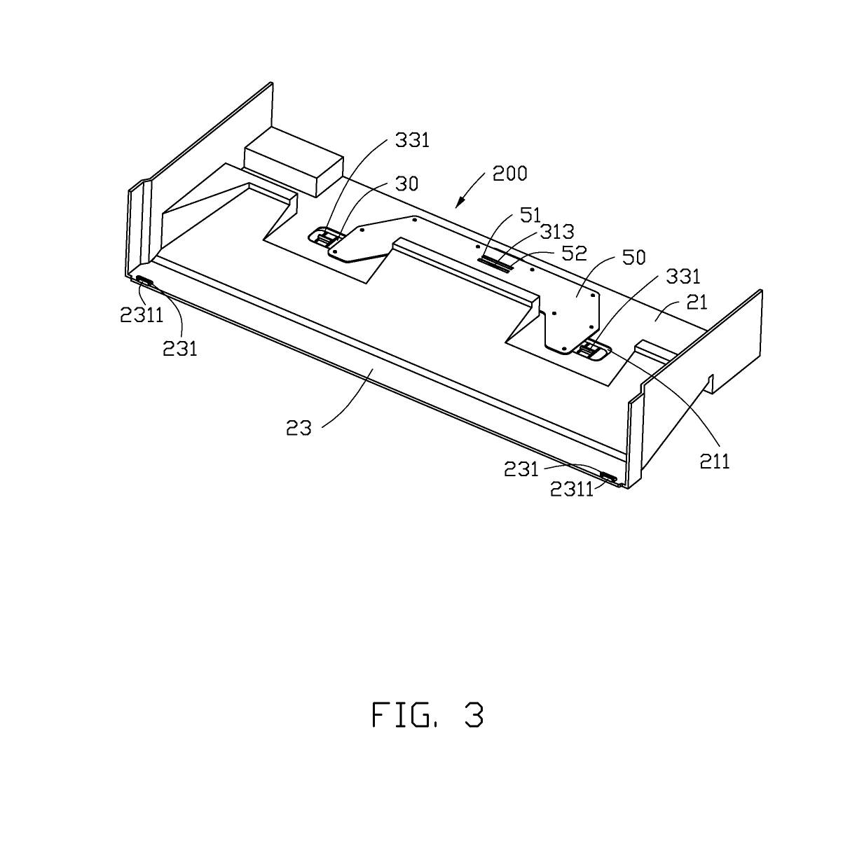

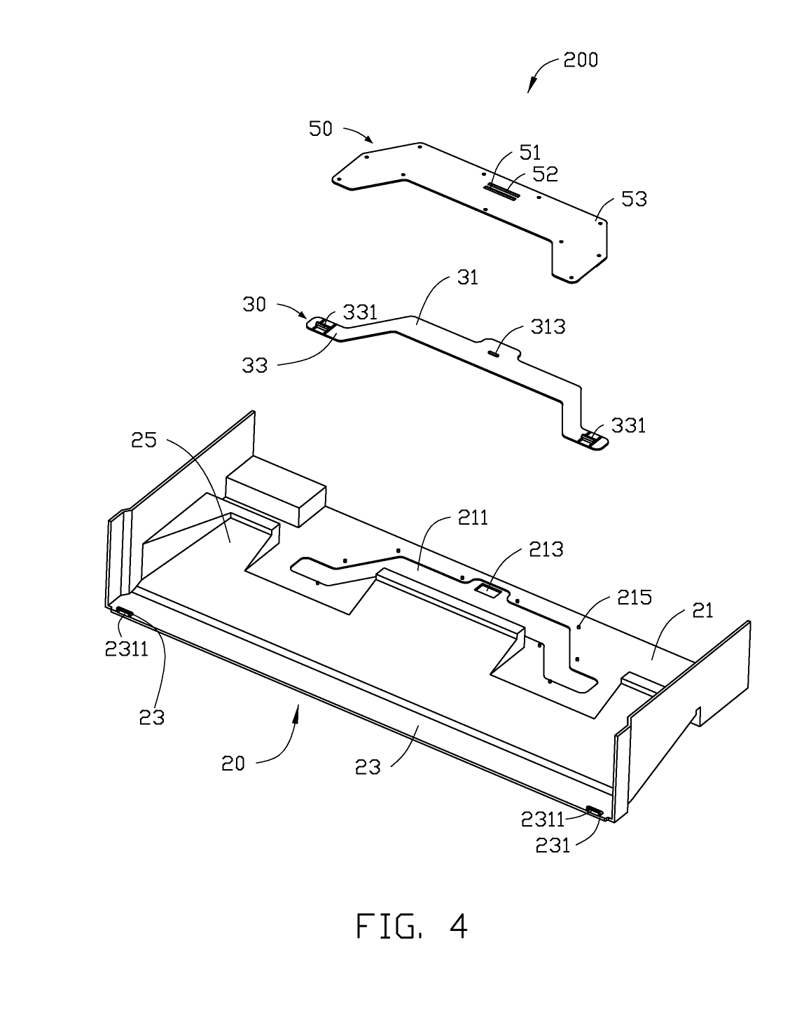

FIGS. 1, 3, and 4 show the air guiding module 200 including an air guiding duct 20, a sliding member 30, and a limiting member 50.

The air guiding duct 20 includes a top wall 21, a maintaining wall 23, and a slanting wall 25 connected to the maintaining wall 23 and the top wall 21. In one embodiment, the top wall 21 is substantially parallel to the maintaining wall 23. A bottom surface of the top wall 21 defines a receiving slot 211, and the receiving slot 211 does not extend through the top wall 21. The top wall 21 defines a through hole 213 extending through the top wall 21. The through hole 213 is located in the receiving slot 211. A plurality of limiting posts 215 extend from the top wall 21 surrounding the receiving slot 211. An installation portion 231 extends from each of two end portions of the maintaining wall 23. The installation portion 231 defines an installation hole 2311. In one embodiment, a length of the maintaining wall 23 is substantially equal to a length of the handle 231.

The limiting member 30 includes a sliding plate 31 and two extensions 33 extending from opposite ends of the sliding plate 31. An operation block 311 extends from the sliding plate 31 towards the air guiding duct 20. The operation block 313 can be received in the through hole 213. A limiting block 313 protrudes from the sliding plate 31 towards the limiting member 50. A securing block 331 protrudes from the extension 33 towards the limiting member 50.

The limiting member 50 defines a first limiting slot 51, a second limiting slot 52, and a plurality of limiting holes 53. Each limiting hole 53 corresponds to each limiting post 215. In one embodiment, the first limiting slot 51 is substantially parallel to the second limiting slot 52.

In assembly of the air guiding module 200, the sliding member 30 is moved to position in the receiving slot 211, and the operation block 311 extends out of the through hole 213. The limiting member 50 is moved to be adjacent to the air guiding duct 20 to align the limiting hole 53 to the limiting post 215, and the first limiting slot 51 is aligned to the limiting block 313. The limiting member 50 is pressed and moved towards the air guiding duct 20, the limiting post 215 is engagingly received in the limiting slot 211, and the limiting block 30 is engagingly received in the first limiting slot 51. In this position, the sliding member 30 is in a first position. The operation block 311 is operable to slide the sliding member 30 relative to the air guiding duct 20 in the receiving slot 211. When the limiting member 30 is slid away from the maintaining wall 23, the limiting block 313 is disengaged from the first limiting slot 51 and engagingly received in the second limiting slot 52. In this position, the sliding member 30 is in a second position. When the sliding member 30 is slid towards the maintaining wall 23, the limiting block 313 is disengaged from the second limiting slot 52 and engagingly received in the first limiting slot 51, and the sliding member 30 is back to the first position. In one embodiment, the limiting post 215 is secured in the limiting hole 53, and there is an interference fit between the limiting post 215 and the limiting hole 53.

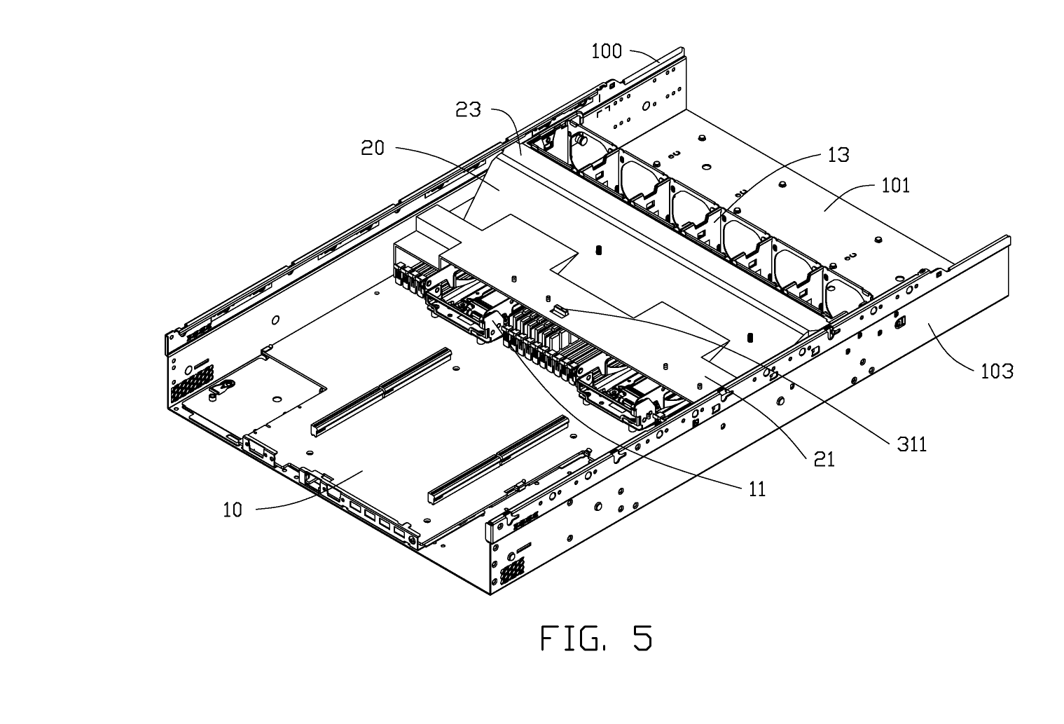

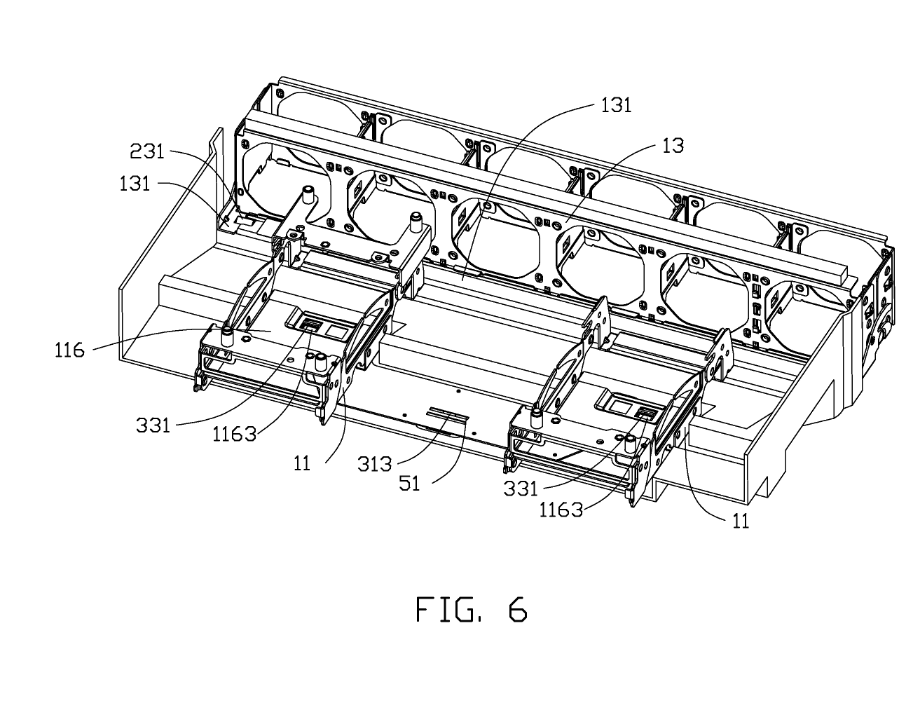

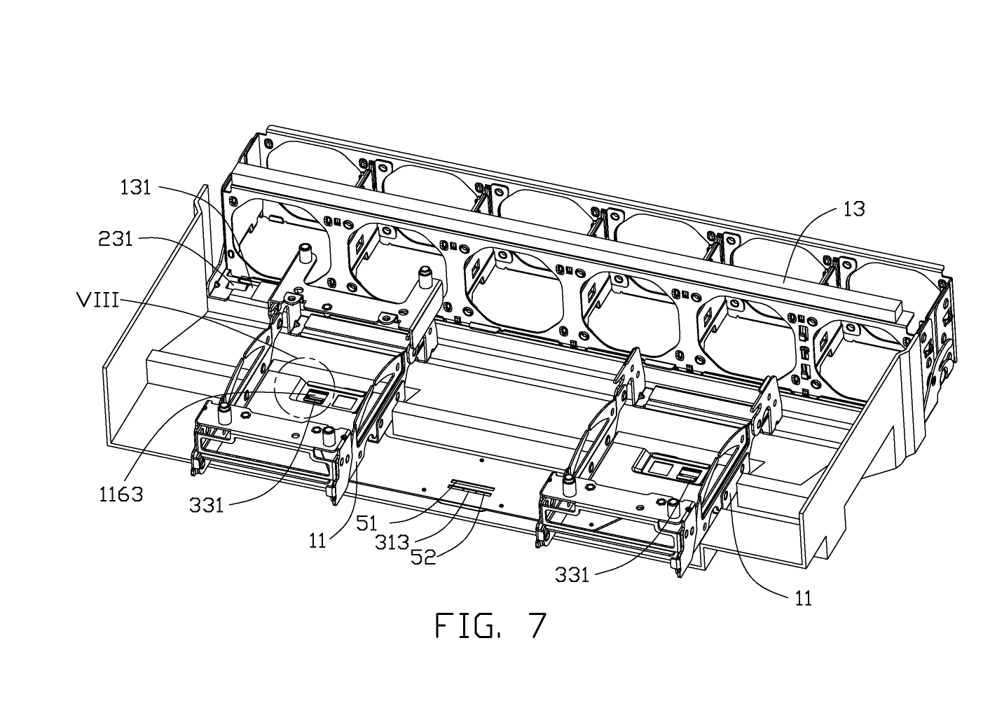

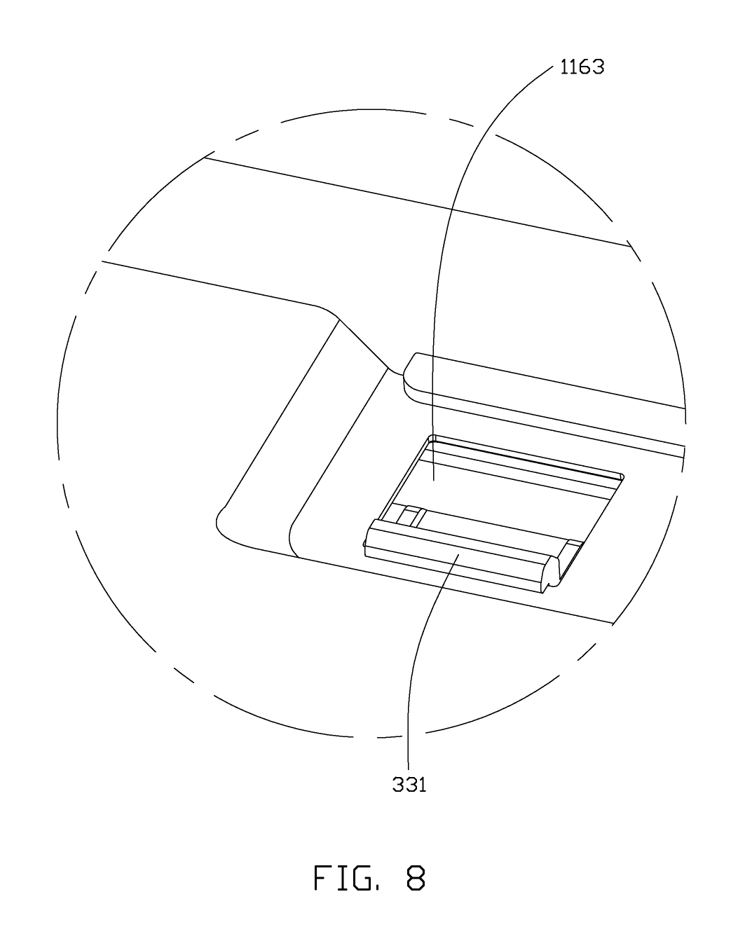

FIGS. 5-8 show that in assembly of the air guiding module 200 to the enclosure 100, the sliding member 30 is slid to the first position. The air guiding module 200 is slantingly located to extend the installation portion 231 into the installation slot 131, and the limiting piece 1315 is engagingly received in the installation hole 2311. The air guiding module 200 is rotated towards the bottom plate 101 until abutting the mounting cover 116. In this position, the securing block 331 is received in the mounting hole 1163. The operation block 311 is operated to slide the sliding member 30 to the second position. In this position, the securing block 331 is engaged with edges of the mounting hole 1163. Thus, the air guiding module 200 is secured to the mounting bracket 11 and the handle 131 of the installation bracket 13.

In disassembly, the sliding member 30 is slid to the first position, the securing block 331 is disengaged from the edges of the mounting hole 1163 and slid into the mounting hole 1163. In this position, the air guiding module 200 is removable from the enclosure 100 when being rotated away from the enclosure 100.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. An air guiding module, comprising:
an air guiding duct defining a receiving slot;
a sliding member slidably mounted in the receiving slot; and
a limiting member secured to the air guiding duct and engaging the sliding member in the receiving slot;
wherein the sliding member is slidable relative to the air guiding duct and the limiting member between a first position and a second position; when the sliding member is in the first position, the sliding member disengages the air guiding module from an enclosure; and when the sliding member is in the second position, the sliding member engages the air guiding module with the enclosure.

2. The air guiding module of claim 1, wherein the air guiding duct comprises an installation portion, and the installation portion defines an installation hole; and the installation hole is configured for rotatably receive a limiting piece of the enclosure.

3. The air guiding module of claim 1, wherein the air guiding duct defines a through hole, the sliding member further comprises an operation block extending out of the through hole; and the operation block is operable to slide the sliding member.

4. The electronic device of claim 3, wherein the air guiding duct comprises a top wall, the receiving slot extends from a first surface of the top wall and does not extend out of the top wall; the through hole extends from a second surface of the top wall, which is opposite to the first surface; and the through hole extends through the receiving slot.

5. The air guiding module of claim 1, wherein the sliding member further comprises a limiting block; the limiting member defines a first limiting slot and a second limiting slot;
when the sliding member is in the first position, the limiting block is engaged in the first limiting slot; and when the sliding member is in the second position, the limiting block is engaged in the second limiting slot.

6. The air guiding module of claim 5, wherein the second limiting slot is substantially parallel to the first limiting slot.

7. An electronic device, comprising:
an enclosure;
an installation bracket secured to the enclosure;
a mounting bracket secured to the enclosure; and
an air guiding module comprising:
an air guiding duct with a first end rotatably mounted to the installation bracket, and the air guiding duct defining a receiving slot;
a sliding member slidably mounted in the receiving slot; and
a limiting member secured to the air guiding duct and engaging the sliding member in the receiving slot;
wherein the sliding member is slidable relative to the air guiding duct and the limiting member between a first position and a second position; when the sliding member is in the first position, the sliding member is disengaged from the mounting bracket, allowing the air guiding duct to rotate relative to the enclosure to disengage from the enclosure; and when the sliding member is in the second position, the sliding member is secured to the mounting bracket, preventing the air guiding duct from rotating relative to the enclosure.

8. The electronic device of claim 7, wherein the air guiding duct comprises an installation portion, and the installation portion defines an installation hole; the installation bracket is configured to secure a plurality of fans and comprises a handle, and the handle defines an installation slot and comprises a limiting piece extending from an edge of the installation slot; the installation portion is received in the installation slot; and the limiting piece is rotatably received in the installation hole.

9. The electronic device of claim 7, wherein the air guiding duct defines a through hole, the sliding member further comprises an operation block extending out of the through hole;
and the operation block is operable to slide the sliding member.

10. The electronic device of claim 7, wherein the mounting bracket is configured to secured a CPU and defines a mounting hole; the sliding member further comprises a securing block slidably received in the mounting hole; when the sliding member is in the first position, the securing block is received in the mounting hole; and when the sliding member is in the second position, the securing block is engaged with edges of the mounting hole.

11. The electronic device of claim 7, wherein the sliding member further comprises a limiting block; the limiting member defines a first limiting slot and a second limiting slot; when the sliding member is in the first position, the limiting block is engaged in the first limiting slot; and when the sliding member is in the second position, the limiting block is engaged in the second limiting slot.

12. The electronic device of claim 11, wherein the second limiting slot is substantially parallel to the first limiting slot.

13. An electronic device, comprising:
an enclosure;
an installation bracket secured to the enclosure;
a mounting bracket secured to the enclosure and defining a mounting hole; and
an air guiding module comprising:
an air guiding duct with a first end rotatably mounted to the installation bracket, and the air guiding duct defining a receiving slot;
a sliding member slidably mounted in the receiving slot and comprising a securing block; and
a limiting member secured to the air guiding duct and engaging the sliding member in the receiving slot;
wherein the sliding member is slidable relative to the air guiding duct and the limiting member between a first position and a second position; when the sliding member is in the first position, the securing block is received in the mounting hole to disengage the sliding member from the mounting bracket, allowing the air guiding duct to rotate relative to the enclosure to disengage from the enclosure; and when the sliding member is in the second position, the securing block is engaged with edges of the mounting hole to secure the sliding member to the mounting bracket, preventing the air guiding duct from rotating relative to the enclosure.

14. The electronic device of claim 13, wherein the air guiding duct comprises an installation portion, and the installation portion defines an installation hole; the installation bracket is configured to secure a plurality of fans and comprises a handle, and the handle defines an installation slot and comprises a limiting piece extending from an edge of the installation slot; the installation portion is received in the installation slot; and the limiting piece is rotatably received in the installation hole.

15. The electronic device of claim 13, wherein the air guiding duct defines a through hole, the sliding member further comprises an operation block extending out of the through hole; and the operation block is operable to slide the sliding member.

16. The electronic device of claim 15, wherein the air guiding duct comprises a top wall, the receiving slot extends from a first surface of the top wall and does not extend out of the top wall.

17. The electronic device of claim 16, wherein the through hoe extends from a second surface of the top wall, which is opposite to the first surface; and the through hole extends through the receiving slot.

18. The electronic device of claim 13, wherein the mounting bracket is configured to secured a CPU therein.

19. The electronic device of claim 13, wherein the sliding member further comprises a limiting block; the limiting member defines a first limiting slot and a second limiting slot;
when the sliding member is in the first position, the limiting block is engaged in the first limiting slot; and when the sliding member is in the second position, the limiting block is engaged in the second limiting slot.

20. The electronic device of claim 19, wherein the second limiting slot is substantially parallel to the first limiting slot.
